(19) United States
(12) Patent Application Publication
(10) Pub. No.: US 2002/0003236 A1
(43) Pub. Date: Jan. 10, 2002

(54) Electrostatic discharge protective structure

(76) Inventors: Martin Czech, Freiburg (DE); Peter Graf, Teningen-Nimburg (DE)

Correspondence Address: Samuels, Gauthier & Stevens LLP, Suite 3300, 225 Franklin Sreet, Baston, MA, 02110, US

(21) Appl. No.: 09/852,123

(22) Filed: May 8, 2001

(30) Foreign Application Priority Data
May 8, 2000 (DE) 100 22 366.4

(51) Int. Cl. H01L 29/74; H01L 31/111

(52) U.S. Cl. 257/173

(57) ABSTRACT

An electrostatic discharge (ESD) protective structure is configured to protect an integrated circuit, which is connected between a first voltage bus with a first supply voltage and a second voltage bus with a second supply voltage. The ESD protective structure includes a plurality of laterally designed bipolar transistors, whose load lines are arranged parallel to one another and between the voltage buses, and whose control connections are connected to one of the voltage buses. A single track resistor is co-integrated into the semiconductor body and precedes every control connection of the bipolar transistors.

### CROSS REFERNCE TO RELATED APPLICATIONS

This application contains subject matter related to co-pending application designated Ser. No. ______ , filed May 8, 2001 and entitled “Electrostatic Protective Structure”.

### BACKGROUND OF THE INVENTION

The invention relates to the field of semiconductor devices, and in particular to an electrostatic discharge (ESD) protective structure to protect an integrated semiconductor circuit against electric discharge.

During the operation of integrated circuits undesirably high voltage peaks may occur, which are coupled into the integrated circuit through the supply lines. Without suitable protective measures, parasitic overvoltages of a few volts and the electrostatic discharges caused thereby can damage and even destroy the integrated circuit. This makes the failure rate of such an integrated circuit unacceptably high.

To reduce their failure rate, circuits located on an integrated circuit often contain co-integrated ESD protective structures. These ESD protective structures can be inserted as clamping circuits between the supply lines of the integrated circuit and, in case of an electrostatic discharge, drain off the parasitic overvoltage to one of the supply lines. As a result, the parasitic overvoltage between the supply lines is reduced to a tolerable value (i.e., to a value that does not damage the integrated circuit).

An important boundary condition in the production of ESD protective structures derives from the requirement that under operational conditions (as these are described for example in the product specification) the ESD protective structures must not impair the function of the integrated semiconductor circuit that is being protected (or impair it only insignificantly). Thus the breakdown or switch-through voltage of the ESD protective element must be beyond the nominal signal voltage range of the circuit being protected. As a result, the ESD protective element should break down before the critical circuit path, but beyond the signal voltage range. As a rule this requires an exact adjustment of the breakdown and switch-through voltage of the particular ESD protective element.

ESD protective elements often include semiconductor components that are blocking at least part of the time, such as, for example, thyristors, bipolar transistors, field effect transistors, or diodes.

However, ESD diodes have the disadvantage that at very high currents the voltage drop across the diode may become so large that sensitive components of the protected circuit may be irreversibly damaged (e.g., their gate oxides or diffusion regions). Furthermore, in reverse operation, diodes consume a great deal of power.

A disadvantage of ESD thyristors is that once it fires it retains its firing state in an undesirable manner. This firing state may last arbitrarily long and cause a short circuit in the voltage supply and the destruction of the ESD protective structure, thus damaging the component.

For the above reasons, ESD protective structures are often used that have a plurality of parallel, bipolar field oxide transistors as ESD protection. These ESD protective structures are especially well suited to limit parasitic overvoltages. With a reverse bias voltage in the characteristic, they first show a blocking behavior, until a first voltage breakthrough is reached, at which the current-voltage characteristic snaps back to a lower voltage than the breakthrough voltage. This process of snapping back to the lower, so-called holding voltage, is also called snapback behavior. After the holding voltage has been reached, the current-voltage characteristic has an essentially linear slope until it reaches a second voltage breakthrough, at which the ESD protective structure is destroyed, and obviously must be avoided. The plurality of ESD transistors arranged in parallel consequently should switch through as uniformly and as simultaneously as possible in response to a coupled-in overvoltage pulse.

However, ESD protective structures are at risk that one or a few bipolar transistors will pull the entire ESD current to themselves, and thus the second voltage breakthrough will be reached prematurely resulting in a short circuit. This short circuit caused by an inhomogeneous current flow may in the same manner short circuit the supply voltage of the entire integrated semiconductor circuit. Without additional protective measures this can have catastrophic consequences (i.e., the destruction of the integrated circuit). When a plurality of transistors is used as ESD protection, there is a need to distribute an ESD current caused by electrostatic overvoltage uniformly in the semiconductor body of the ESD protective structure, so that the ESD protective structure can be loaded to the greatest extent and thus damage of the ESD protective structure is prevented.

Therefore, there is a need for an ESD protective structure that assures that the transistors of the ESD protective structure switch on as uniformly as possible.

### SUMMARY OF THE INVENTION

Briefly, according to an aspect of the present invention, an electrostatic discharge (ESD) protective structure is configured to protect an integrated circuit, which is connected between a first voltage bus with a first supply voltage and a second voltage bus with a second supply voltage. The ESD protective structure includes a plurality of laterally designed bipolar transistors, whose load lines are arranged parallel to one another and between the voltage buses, and whose control connections are connected to one of the voltage buses. A single track resistor is co-integrated into the semiconductor body and precedes every control connection of the bipolar transistors.

The ESD protective structure has a single common track resistor that actuates each bipolar transistor. The track resistor is created by a deep implantation region or diffusion region inserted in the semiconductor body. These deep doping regions act like an artificially expanded distance or a barrier between the base zone and the region in which the collector zones and emitter zones are situated. Charge carriers are thus artificially prevented from diffusing directly to the base zones and take a detour into the depth of the substrate. The charge carriers created at a first voltage breakthrough are predominantly held back in a region below the emitter zones and collector zones, which favors a subsequent firing process. Since the region below the collector and emitter contains a defined and essentially uniformly distributed quantity of charge carriers the bipolar transistors of the ESD protective structure fire quickly and uniformly.

In a preferred embodiment, the well-like regions are connected to the outermost zones of the first conduction type (e.g., the outermost emitter zones), and they have the same conduction type as these (emitter) zones. The well-like regions then lie at the same potential as the (emitter) zones. This assures that the charge carriers traverse a much longer path through the substrate of the semiconductor body in order to reach the base zones. However, the well-shaped regions typically have a much lower doping concentration than the connected (emitter) zones. It is contemplated that the well-shaped regions may not be doped, or may include a dielectric.

In a preferred embodiment the well-shaped regions extend much deeper into the semiconductor body than those (emitter) zones that they adjoin or to which they are connected. In this case, the well-shaped regions can be produced, for example, by multiple ion implantation or by diffusion with a subsequent deep drive-in step. It is contemplated that a conventional trench etching process and filling up with doped or undoped polysilicon or with a dielectric may be performed.

The emitter zones and the collector zones typically are surrounded laterally by the base zones and the well-shaped regions. This assures better latch-up protection for the ESD protective structure. This latch-up protection may be improved further if the zones of the ESD structure (i.e., the emitter zones, the collector zones, the base zones, and the well-shaped regions) are embedded in an additional well and thus are isolated from the substrate potential.

In one embodiment, the emitter zones and collector zones are designed in strips. The strip-shaped collector zones and emitter zones are arranged parallel to one another, such that the collector zones and emitter zones alternate. The ESD protective structure may be configured and arranged in an essentially square layout, which assures significant homogenization of the current of the ESD structure. Further homogenization of the current can be achieved in that the emitter zones and collector zones are through-contacted by the respective electrodes.

In one embodiment each of the strip-shaped emitter electrodes and collector electrodes forms a finger-like structure with the conductor track to which they are connected. These finger-like structures are preferably staggered with one another. As a result, large current densities and large voltage drops occur at opposite sides of the respective conductor tracks, thus reducing scorching at the conductor tracks caused by voltage breakthroughs.

The ESD protective structure is especially suited for bipolar transistors designed as field oxide transistors.

These and other objects, features and advantages of the present invention will become more apparent in light of the following detailed description of preferred embodiments thereof, as illustrated in the accompanying drawings.

### BRIEF DESCRIPTION OF THE DRAWING

FIG. 1 illustrates a circuit arrangement with an inventive ESD protective structure;

FIG. 2 illustrates a circuit diagram of the inventive ESD protective structure illustrated in FIG. 1, including three bipolar transistors;

FIG. 3 illustrates a partial section through an embodiment of the ESD protective structure illustrated in FIG. 2;

FIG. 4 is a top view of an arrangement for contacting the emitter, base, and collector of the ESD protective structure illustrated in FIG. 3; and

FIG. 5 is a top view of an arrangement of the conductor tracks for contacting the emitter electrodes and collector electrodes.

### DETAILED DESCRIPTION OF THE INVENTION

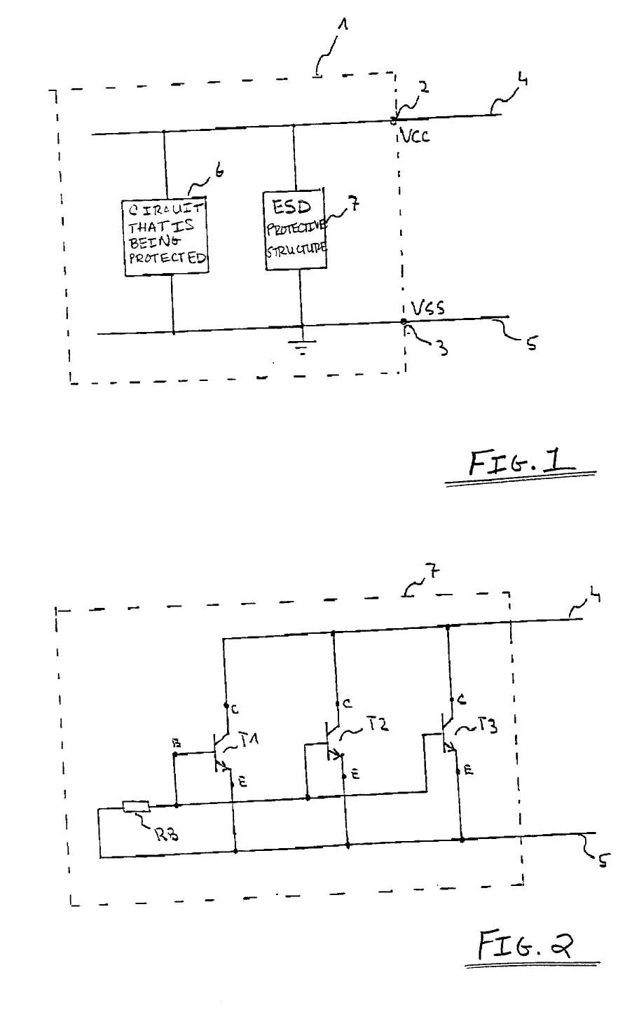

FIG. 1 illustrates an integrated circuit 1. The integrated circuit 1 is connected via supply voltage inputs 2, 3, to a first voltage bus 4 with a first supply voltage VCC and to a second voltage bus 5 with a second supply voltage VSS, respectively. In the present example VSS is reference ground.

The integrated circuit 1 includes a circuit 6 that is being protected (e.g., a logic circuit, a program-controlled unit, a semiconductor memory, a power circuit, etc.). The integrated circuit 1 also includes an ESD protective element 7 to protect the circuit 6. The circuit 6 that is being protected and the ESD protective element 7 are connected between the voltage buses 4, 5.

FIG. 2 illustrates a circuit arrangement of the inventive ESD protective 7. The ESD protective structure 7 includes a plurality of (e.g., three) bipolar field oxide transistors T1, T2, T3. The bipolar transistors T1-T3 are arranged in parallel across their load lines and are connected between the voltage buses 4, 5. In the present embodiment, the respective emitter connections E are connected to the voltage of the reference ground VSS, and the respective collector connections C are connected to the supply voltage VCC. According to an aspect of the invention, the base connections B of the bipolar transistors T1-T3 are short-circuited with one another and are coupled, via a track resistor RB to the reference voltage VSS and thus the emitter connections E.

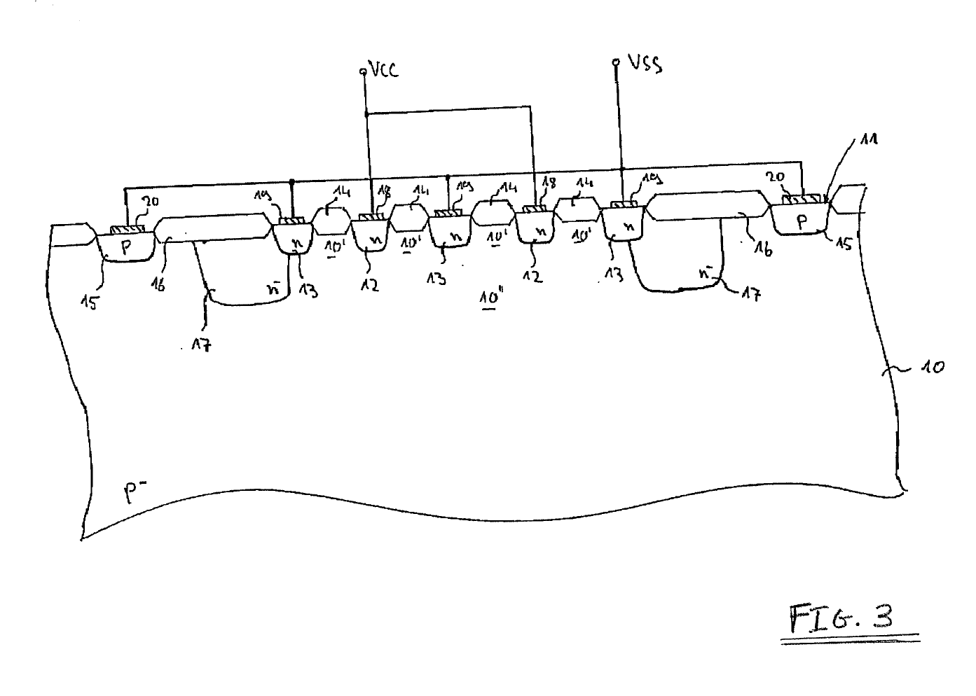

FIG. 3 illustrates a partial section of the ESD protective structure of FIG. 2. In one embodiment a semiconductor body 10 includes a weakly p-doped silicon substrate. The semiconductor body 10 has a wafer front side 11 in which are embedded the first and second n-doped regions 12, 13. The first n-doped regions 12 are the collector zones in the present embodiment; the second n-doped regions 13 are the emitter zones. The collector zones 12 and the emitter zones 13 are arranged alternately on the surface 11, and they are spaced apart from one another by a substrate zone 10′ or field oxide 14. P-doped regions 15 that form the base zones are embedded in the semiconductor body 10. The base zones 15 enclose the collector zones 12 and emitter zones 13 and are spaced apart from these for example by a field oxide 16.

The collector zones 12, the emitter zones 13, and the base zones 14 are respectively contacted through contact electrodes 18, 19, 20 at the surface 11 of the semiconductor body 10. The collector electrodes 18 are short-circuited with one another and are connected to the first supply voltage VCC. The emitter electrodes 19 and the base electrodes 20 are also short-circuited with one another and are connected to the voltage of the reference ground VSS.

According to an aspect of the present invention, well-shaped regions 17 are introduced into the semiconductor body 10 between the base zones 15 and the outer n-doped regions 12, 13 (in the present embodiment these are the outer emitter zones 13). These well-shaped regions are connected to the outer emitter zones 13. The well-shaped regions 17 have the same conduction type as the emitter zones 13, but a lower dopant concentration. However, they may also be undoped or can contain a dielectric. Furthermore, the regions 17 do not necessarily have to be well-shaped, but, in the context of the technology used to produce the particular integrated semiconductor circuit, they can also be for example trench-shaped.

The lateral and/or vertical dimensions of the well-shaped regions 17 are such that the effective drift path of charge carriers between the p-doped base zones 15 and the substrate zones 10′ in the semiconductor substrate 10 are markedly lengthened. The regions 17, therefore, are advantageously introduced much deeper into the semiconductor body 10 than the corresponding emitter zones 13 and/or collector zones 12.

The function of the inventive ESD protective structure 7 will be explained in more detail below. According to an aspect of the invention, the weakly n-doped well-shaped regions 17 are melded together with the outer n-doped emitter zones 13 and consequently are at the reference voltage VSS. Depending on the technological process used these well-shaped regions 17 can be created by high-energy ion implantation or by deep diffusion. They hinder the charge carriers created at a first voltage breakthrough from diffusing away rapidly into the substrate and thus into the base zones, since the effective path to these base zones 15, which act as substrate contact, has been markedly extended through the well-shaped region 17. Thus, the region 10″ below the emitter zones 13 and collector zones 12 is filled up relatively quickly with charge carriers, which significantly favors a subsequent firing process. Because a defined and essentially uniformly distributed quantity of charge carriers is situated in the region 10″, it can be assured that the bipolar transistors T1-T3 of the ESD protective structure 7 fire quickly and uniformly. In this way, a more uniform and much greater common base resistance RB is achieved for all the bipolar transistors T1-T3 of the ESD protective structure 7.

FIG. 4 illustrates a top view of a layout of an ESD protective structure 7 corresponding to FIG. 2. The entire ESD protective structure 7 preferably has an essentially square layout, which favors uniform current distribution among the various bipolar transistors T1-T3. In this square layout the emitter zones 13 and the collector zones 12 are formed as strips that are arranged parallel to one another. This assures that none of the bipolar transistors T1-T3 in principle “sees” different substrate effects than the respectively adjoining bipolar transistor T1-T3. Furthermore, a square layout prevents the voltage drop of the contact metallization from becoming too large and the creation of a non-uniform current distribution, as would be the case for example for a rectangular non-square layout.

The invention is not limited to square layouts of the ESD protective structures 7. It is contemplated that non-square layouts such as rectangular, round, oval, or hexagonal or similar layouts may also be used. Furthermore, the emitter and collector zones 12, 13 need not necessarily be arranged as strips next to one another, but rather may be arranged in circles, squares, serpentines, fanned-out, or the like. The emitter zones 13, collector zones 12, and base zones 15 are through-contacted as much as possible by the respective electrodes 18, 19, 20 to promote homogenization of the current flow.

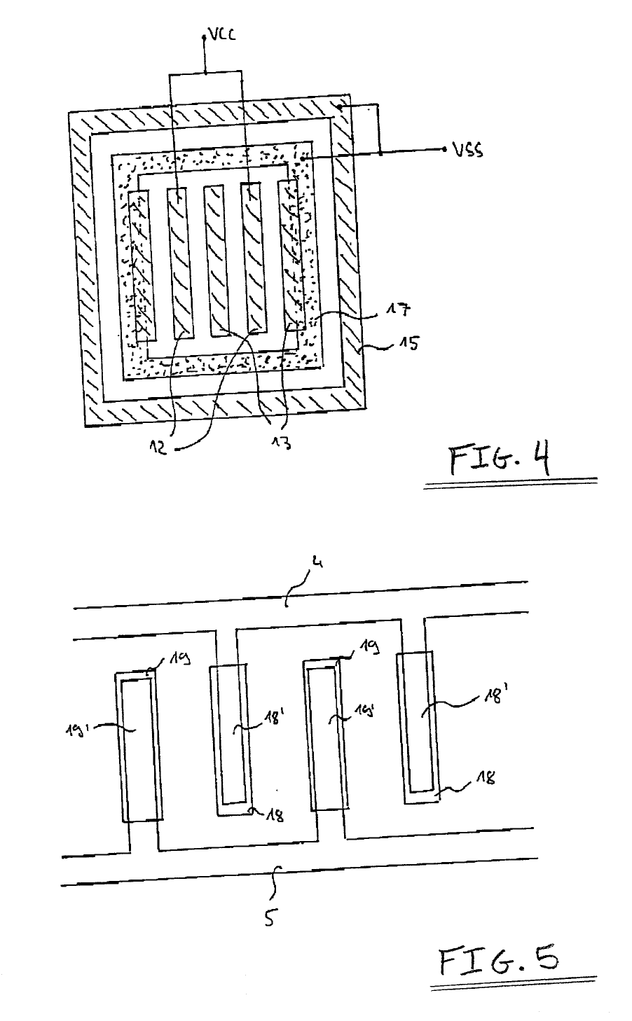

FIG. 5 illustrates a top view of an arrangement of the conductor tracks for contacting the emitter electrodes and the collector electrodes. This view illustrates two metallizations for the voltage busses 4, 5. Furthermore, FIG. 5 shows the respective strip-shaped emitter electrodes 19 and collector electrodes 18, arranged next to one another. These electrodes 18, 19 are connected, via finger-shaped metallizations 18′, 19′, to their respectively associated voltage busses 4, 5. In this arrangement the metallization fingers 18′, 19′ are staggered and are connected to the mutually opposite voltage buses 4, 5, respectively.

During operation of the ESD protective structure 7 there are unavoidable voltage drops at its electrodes 18, 19, such that usually the greatest voltage difference between emitter and collector appears at the front ends of the electrodes 18, 19. Consequently, the current densities are highest there and the electrodes 18, 19 may break down due to scorching. The arrangement of the metallization fingers 18′, 19′ shown in FIG. 5 essentially precludes this problem, since the metallization fingers 18′, 19′ are connected only to one of the opposite voltage buses 4, 5. Voltage drops still occur along the respective metallizations, but with an alternating collector electrode 18 and emitter electrode 19 they occur in opposite directions so that a voltage difference between the collector electrode 18 and the emitter electrode 19 remains the same. In addition, the layout measure of FIG. 5 favors a more homogeneous current distribution on the entire surface of the ESD protective structure 7.

The ESD protective structure may be arranged next to one another arbitrarily often. It should be noted here that the p-doped base zones 15 are preferably arranged outside, and the collector zones 12 and emitter zones 13 are surrounded by them. Because the base zones 15 surround the zones 12, 13, the ESD protective structure 7 is held at a defined voltage thus assuring improved latch-up protection. However, it is contemplated that the base zones 15 do not completely enclose the zones 12, 13, but such a structure offers lesser latch-up protection.

The ESD protective structure described in the embodiments has only three bipolar transistors T1-T3; in the layout, this ESD protective structure consequently has three emitter fingers and two collector fingers. Of course, the present invention can also be implemented with more or fewer bipolar transistors T1-T3. An important point here is symmetry, that is the emitter zones 13 and collector zones 12 are arranged as symmetrically to one another as possible. Furthermore, the emitters should lie outside as much as possible, so as to exclude parasitic edge effects.

The base zones 15, collector zones 12, and emitter zones 13 illustrated in FIG. 3 may be introduced into the semiconductor body 10 by diffusion or by ion implantation. The selected doping method is essentially guided in accordance with the particular manufacturing processes for the integrated circuit.

With respect to the embodiments illustrated in FIGS. 3 and 4, it is contemplated that conductively types n and p may be interchanged. Furthermore, for the sake of completeness, it should be pointed out that the lateral and vertical dimensions in FIG. 3 naturally have not been shown to scale. For example, for the sake of ease of illustration, the vertical dimensions are shown greatly magnified compared to the lateral dimensions.

The ESD protective structure 7 described above avoids the problems of the inhomogeneous current flow with concomitant rapid destruction of the ESD protective structure. A solution of the problem is achieved almost exclusively by device layout control, and consequently requires no expensive special processes or special masks. Only a very slight extra expense for chip surface is needed here; however, the self-protective effect of the above-described ESD protective structure can be substantially increased thereby.

The inventive ESD protective structure is especially suited for MOS-/CMOS-integrated semiconductor circuits, which require protection of the supply voltage lines and also of the inputs and outputs. This includes integrated circuits with analog and digital functions with their own analog supply voltage, especially such circuits as operate at a high operating voltage and thus do not have inherent protection.

The inventive ESD protective structure constructed and operated as described assures optimal ESD protection by the insertion of merely one deep implantation or diffusion for the well-shaped region, without at the same time having to accept the disadvantages of the prior art ESD protective structure with a large number of bipolar transistors.

Although the present invention has been shown and described with respect to several preferred embodiments thereof, various changes, omissions and additions to the form and detail thereof, may be made therein, without departing from the spirit and scope of the invention.

What is claimed is:

1. An electrostatic discharge (ESD) protective structure that protects an integrated circuit connected between a first voltage bus with a first supply voltage (VCC) and a second voltage bus with a second supply voltage (VSS), said electrostatic discharge protective structure comprising:
a plurality of laterally designed bipolar transistors each having a first load line connected to the first voltage bus and a second load line connected to the second voltage bus, wherein said first load lines are electrically parallel and said second load lines are electrically parallel to one another, each of said transistors includes a control connection connected to one of the voltage buses;
a single track resistor (RB) co-integrated into a semiconductor body, wherein said single track resistor precedes every control connection (B) of said bipolar transistors (T1-T3).

2. The electrostatic discharge protective structure of claim 1, wherein said semiconductor body has embedded therein at least one emitter zone and at least one collector zone of the first conduction type and at least one base zone of the second, opposite conduction type, wherein a well-shaped region is inserted into said semiconductor body between said zones of the first conduction type and said base zones, so as to extend the effective mean free path of the charge carriers to said base zone.

3. The electrostatic discharge protective structure of claim 2, wherein said well-shaped region is connected to one of said zones of the first conduction type.

4. The electrostatic discharge protective structure of claim 3, wherein said well-shaped region has the same conduction type as said zone to which it is connected, but has a lower dopant concentration.

5. The electrostatic discharge protective structure of claim 4, wherein said well-shaped region extends deeper into said semiconductor body than said zone which it adjoins or to which it is connected.

6. The electrostatic discharge protective structure of claim 5, wherein said base zones laterally enclose said emitter zones at said collector zones.

7. The electrostatic discharge protective structure of claim 6, wherein said semiconductor body has charge carriers of the first conduction type and that at least one further well of the second conduction type is embedded in said semiconductor body, and that said emitter zones, collector zones, and base zones and said well-shaped regions are embedded in said well.

8. The electrostatic discharge protective structure of claim 7, wherein said emitter zones and collector zones are designed as strips and are disposed alternatingly next to one another and parallel to one another.

9. The electrostatic discharge protective structure of claim 8, wherein said electrostatic discharge protective structure is configured and arranged in an essentially square layout.

10. The electrostatic discharge protective structure of claim 9, wherein in said emitter zones are through-contacted by said emitter electrodes, and said collector zones are through-contacted contacted by said collector electrodes.

11. The electrostatic discharge protective structure of claim 8, wherein said emitter electrodes and said collector electrodes are connected via conductor tracks to oppositely situated voltage buses and form finger-like connections which are staggered with one another.

12. The electrostatic discharge protective structure of claim 8, wherein said bipolar transistors (T1-T3) are designed as field oxide transistors.
